(19) United States
(12) Patent Application Publication
(10) Pub. No.: US 2025/0385073 A1
(43) Pub. Date: Dec. 18, 2025

(54) POSITIONING IN A CHARGED PARTICLE PROCESSING SYSTEM

(71) Applicant: Multibeam Corporation, Santa Clara, CA (US)

(72) Inventors: Eliyahu Vronsky, San Francisco, CA (US); Michael Baker, Santa Clara, CA (US); David Darrow, Pleasanton, CA (US); Andrew Ceballos, Mountain View, CA (US); Tsenguun Byambadorj, San Jose, CA (US)

(73) Assignee: Multibeam Corporation, Santa Clara, CA (US)

(21) Appl. No.: 18/828,231

(22) Filed: Sep. 9, 2024

Related U.S. Application Data
(60) Provisional application No. 63/661,397, filed on Jun. 18, 2024.

(51) Int. Cl. H01J 37/304; G06T 7/00; G06T 7/246; G06T 7/73; H01J 37/20; H01J 37/22

(52) U.S. Cl. CPC H01J 37/3045; G06T 7/001; G06T 7/248; G06T 7/74; H01J 37/20; H01J 37/222; G06T 2207/30148; H01J 2237/202

(57) ABSTRACT

Methods of processing substrates in a processing tool having a plurality of miniature modular charged particle devices include obtaining a first digital image of a feature of a movable object using an optical inspection system; determining a first position of the movable object based on the digital image using readings from a first plurality of position sensors having a first accuracy; based on the first position, and a predetermined dimension of the processing tool, moving the movable object such that the feature is within an exposure area of a charged particle device; obtaining a second digital image of the feature using the charged particle device; and determining a second position of the movable object based on the second digital image and readings from a second plurality of position sensors. Other methods include using a second charged particle device to perform a print plan when a first device is not operated.

### CROSS-REFERENCE TO RELATED APPLICATIONS

This patent application claims priority benefit of U.S. Provisional Patent Application Ser. No. 63/661,397 filed Jun. 18, 2024, which is entirely incorporated herein by reference.

### FIELD

Embodiments relate to a system for treating substrates using charged particles. In particular, this application is about methods of positioning a substrate and targeting in a system for modular miniature charged particle beam devices that produce charged particles for treatment of a substrate.

### BACKGROUND

Electron beam technologies are used in many manufacturing settings, most notably in semiconductor manufacturing. While electron beam techniques for lithography can enable highly customized variations on a semiconductor wafer, processing an entire workpiece using electron beam lithography can be prohibitively time consuming.

Systems having multiple modular miniature charged particle devices for concurrently processing a single substrate can be used to accelerate charged particle processing. Because charged particles processing typically involves charged particle beams that can have dimensions on the order of a few nanometers to form features of similar sizes on a substrate, substrate positioning and beam targeting are important factors. Methods are needed for expeditiously and accurately positioning a substrate for charged particle processing and for accurately targeting a charged particle beam.

### SUMMARY

Embodiments described herein provide a method, comprising obtaining a first digital image of a feature of a movable object using an optical inspection system of a processing tool having an optical inspection zone and a processing zone, the processing zone having a plurality of charged particle devices for treating a substrate using charged particles; determining a first position of the movable object based on the digital image, a predetermined position of the optical inspection system, and readings from a first plurality of position sensors coupled with the movable object to detect position and movement of the movable object with a first accuracy; based on the first position of the movable object, and a predetermined dimension of the processing tool, moving the movable object to a location in the processing zone of the processing tool such that the feature is within an exposure area of a charged particle device of the plurality of charged particle devices; obtaining a second digital image of the feature of the movable object at the location using the charged particle device; and determining a second position of the movable object based on the second digital image and readings from a second plurality of position sensors coupled with the movable object to detect position and movement of the movable object with a second accuracy higher than the first accuracy.

Other embodiments described herein provide a method, comprising obtaining a first digital image of a feature of a movable object using an optical inspection system of a processing tool having an optical inspection zone and a processing zone, the processing zone having a plurality of charged particle devices; determining a first position of the movable object based on the digital image, a predetermined position of the optical inspection system, and readings from a first plurality of position sensors coupled with the movable object to detect position and movement of the movable object with a first accuracy; based on the first position of the movable object, and a predetermined dimension of the processing tool, determining a second position within an exposure area of a charged particle device of the plurality of charged particle devices; moving the movable object to position the feature at the second position by moving the movable object in a linear direction until readings from the first plurality of position sensors indicate that the feature is located at the second position; obtaining a second digital image of the feature of the movable object at the second position using the charged particle device; and based on the second digital image, and on readings from a second plurality of position sensors coupled with the movable object to detect position and movement of the movable body with a second accuracy higher than the first accuracy, determining an offset of the charged particle device.

Other embodiments described herein provide a method, comprising obtaining a first digital image of a first feature of a movable object using an optical inspection system of a processing tool having an optical inspection zone and a processing zone, the processing zone having a plurality of charged particle devices; determining a first position of the movable object based on the first digital image, a predetermined position of the optical inspection system, and readings from a first plurality of position sensors coupled with the movable object to detect position and movement of the movable object with a first accuracy; based on the first position of the movable object, and a predetermined dimension of the processing tool, determining a second position within an exposure area of a first charged particle device of the plurality of charged particle devices; moving the movable object to position the first feature at the second position by moving the movable object in a linear direction until readings from the first plurality of position sensors indicate that the first feature is at the second position; obtaining a second digital image of the first feature of the movable object at the second position using the first charged particle device; and based on the second digital image, and on readings from a second plurality of position sensors coupled with the movable object to detect position and movement of the movable body with a second accuracy higher than the first accuracy, determining an offset of the first charged particle device; while the first feature is at the second position, obtaining a third digital image of a second feature of the movable object using a second charged particle device of the plurality of charged particle devices; and based on the third digital image, and on readings from the second plurality of position sensors, determining an offset of the second charged particle device.

Other embodiments described herein provide a method, comprising positioning a substrate on a movable substrate support to receive charged particles from a plurality of charged particle devices to the substrate; obtaining a treatment plan defining treatment of portions of the substrate using the plurality of charged particle devices; identifying one or more non-operated charged particle devices of the plurality of charged particle devices that are not to be operated during execution of the treatment plan; identifying a first portion of the treatment plan prescribing use of operated charged particle devices to be operated during execution of the treatment plan and a second portion of the treatment plan prescribing use of non-operated charged particle devices that are not to be operated during execution of the treatment plan; treating the substrate according to the first portion of the treatment plan using the operated charged particle devices; and treating the substrate according to the second portion of the treatment plan using one or more of the operated charged particle devices.

### BRIEF DESCRIPTION OF THE DRAWINGS

Some example embodiments are illustrated, by way of example and not limitation, in the accompanying figures. In the figures, like reference numbers indicate like features, and features might not be drawn to scale.

FIG. 1 is a schematic cross-sectional view of a processing tool according to one embodiment.

FIG. 2 is a schematic plan view of the processing tool of FIG. 1

FIGS. 3A and 3B show a flow diagram summarizing a method 300 according to one embodiment.

FIGS. 4A-4D are activity diagrams of the processing tool of FIG. 1 at various stages of performing the method of FIGS. 3A and 3B.

FIG. 5 is a flow diagram summarizing a method according to another embodiment.

FIG. 6 is an activity diagram depicting capture of an image while performing the method of FIG. 5.

FIGS. 7A-7H are activity diagrams illustrating processing of a substrate using a processing tool that has multiple miniature modular charge particle devices.

FIG. 8 is a flow diagram summarizing a method according to another embodiment.

### DETAILED DESCRIPTION

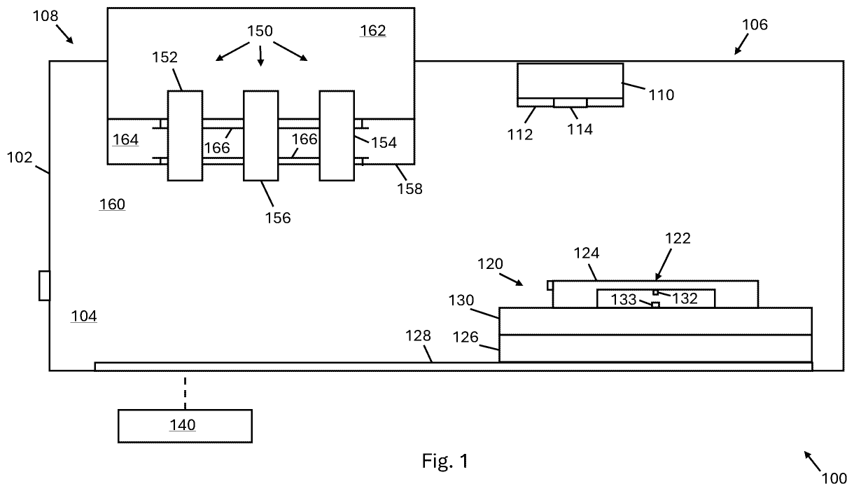

FIG. 1 is a schematic cross-sectional view of a processing tool 100 according to one embodiment. The processing tool 100 has an enclosure 102 that defines an interior 104, which can support a controlled environment for processing a substrate in the interior. Generally, the interior 104 is maintained under high vacuum during substrate processing, for example 10⁻⁷ Torr or less, using pumps suited to such service. The processing tool 100 has an inspection zone 106 and a processing zone 108, corresponding to different parts of the interior 104. The inspection zone 106 and the processing zone 108 are laterally juxtaposed such that the inspection zone 106 can be used for various inspections of a substrate at a location that is not in the processing zone 108 before, or after, processing the substrate in the processing zone 108.

The processing tool 100 has a substrate support 120 for supporting a substrate during processing in the tool 100. The substrate support 120 is disposed in the interior 104, within the enclosure 102, and is movable between the inspection zone 106 and the processing zone 108 of the interior 104. The substrate support 120 has a support surface 122, which is an upper surface of a stage 124, for receiving and supporting a substrate thereon. A first member 126 of the substrate support 120 is supported, in this case, on two rails 128, only one of which is visible in FIG. 1. The rails 128 extend in a substantially parallel manner in a first direction within the interior 104. Here, the rails 128 rest on an interior wall of the enclosure 102, but the rails 128 can be supported using any suitable means. The substrate support 120 is movable along the rails 128 by use of one or more linear actuators (not shown) that couple the substrate support 120 to the rails and propel the substrate support 120 along the rails 128 in either direction along the rails 128. The first member 126 is movable along the rails 128 in the first linear direction so that the substrate support 120 can be moved between the inspection zone 106 and the processing zone 108, which are mutually displaced in the first linear direction, and positioned at any chosen location in the first linear direction.

The substrate support 120 has a second member 130, which is supported on the first member 126 and is movable with respect to the first member 126 in a second linear direction transverse, and substantially perpendicular to, the first linear direction. Movement of the first and second members 126 and 130 places the stage 124 at selected locations within the interior 104 of the tool 100. A controller 140 can be operatively coupled to the processing tool 100 to control movement of the substrate support 120 and position of the stage 124 at selected locations within the interior 104.

The substrate support 120 has a plurality of sensors 132 attached to the stage 124 for sensing location of the stage 124. The sensors 132 can be any suitable variety of sensors, and in many cases linear encoders can be used. In this case, for example, the sensors 132 can be linear encoders, which can be optical, magnetic, and/or capacitive, relying on metric members to measure position and movement of the stage 124. Here, a sensor 132 is located at an interior surface of the stage 124 facing a metric member 133 attached to the second member 130 facing the sensor 132. The metric member is elongated in the second direction so that as the stage 124 moves in the second direction, the sensor 132 can sense metric features on the metric member 133 and output signals representing position of the stage 124 in the second direction. A second sensor and metric member, not visible in FIG. 1, are similarly configured with the first member 126 and second member 130. Sensors and metric members can be deployed in any convenient and suitable manner. In other embodiments, for example, sensors might be located at an outer surface of the stage and metric members might be attached to inner surfaces of the enclosure 102.

For processing by charged particles, it can often be useful to be able to position the stage 124 of the substrate support 120 to an accuracy of less than 100 nm, since for example electron beam processing can form features on a substrate having dimension of a few nanometers. Where encoders are used to control movement of the substrate support 120, the encoders, coupled with the linear actuators used to move and position the stage 124, might be able to position the stage 124 to an accuracy of, perhaps, 1 μm. Such accuracy may be sufficient to position the stage 124 for some operations performed using the tool 100.

For example, the processing tool 100 has an optical inspection station 110 at the inspection zone 106. The optical inspection station 110 comprises a light source 112 and an optical detector 114. Each of the light source and the optical detector 114 can be disposed within the interior 104, for example coupled to an interior wall 116 of the enclosure 102, as shown here, or outside the enclosure 102 to direct light into, or detect light from, the interior 104. Here, the light source 112 is shown surrounding the optical detector 114, like a ring light, but any suitable configuration of light source and detector can be used.

The optical inspection station 110 is generally used for optical inspection of a feature of a movable object within the processing tool 100. The movable object may be the stage 124 of the substrate support 120, or an object such as a substrate disposed on the stage 124. The stage 124 is positioned such that a feature of the movable object is within the field of view of the optical detector 114 such that the optical detector 114 can capture an image of the feature. For such operations, positioning the stage 124 with an accuracy of 10 μm is typically sufficient to position the feature within the field of view of the optical detector 114. For other operations of the processing tool 100, higher accuracy can be helpful, as described further below.

The processing tool 100 has a plurality of charged particle devices 150 disposed in the processing zone 108 of the interior 104. The charged particle devices 150 are arranged to provide a distributed processing area for concurrently processing multiple portions of a substrate using charged particles emitted by the charged particle devices 150. Each of the devices 150 has an emission portion 152 and a direction portion 154. The emission portion 152 emits charged particles, such as electrons, which are collected into the direction portion 154. The direction portion 154 forms the charged particles into a directed stream, which may be a beam. The stream is emitted at an exit end 156 of the direction portion toward a substrate disposed on the stage 124.

The charged particle devices 150 are supported within the interior 104 of the tool 100 by a separation assembly 158, which separates the interior 104 into a first portion 160 and a second portion 162. The exit end 156 of each charged particle device 150 is exposed in the first portion 160, and the emission portion 152 of each charged particle device 150 is within the second portion 162. The separation assembly 158 minimizes or prevents fluid communication between the first portion 160 and the second portion 162, so the first portion 160 and the second portion 162 can be maintained at different operating conditions. For example, the first portion 160, where substrates are processed, can be maintained under high vacuum at a pressure of 10⁻⁷ Torr, or lower, while the second portion 162, where charged particles are formed in the emission portions 152, can be maintained under ultra-high vacuum at a pressure of 10⁻⁹ Torr, or lower.

The separation assembly 158 has an interior portion 164 housing one or more electrical components 166 for powering and/or controlling the charged particle devices 150. The electrical components 166 are generally coupled to each of the charged particle devices 150 such that each charged particle device 150 can be operated at a selected power level different from the other charged particle devices 150 and so that control signals can be sent to the charged particle devices 150 independently. Power supplies can be arranged to provide dedicated service, in some cases, with one power supply dedicated to serving one charged particle device 150, for example. Each of the charged particle devices 150 additionally has local controls, coupled to the direction portion 154 thereof, for controlling aspects of the charged particles such as direction and focus so the charged particle devices 150 can be operated independently to deliver charged particles to portions of a substrate according to any write plan. In any event, the electrical component 166 can be used to route power and control signals to the charged particle devices in any suitable way.

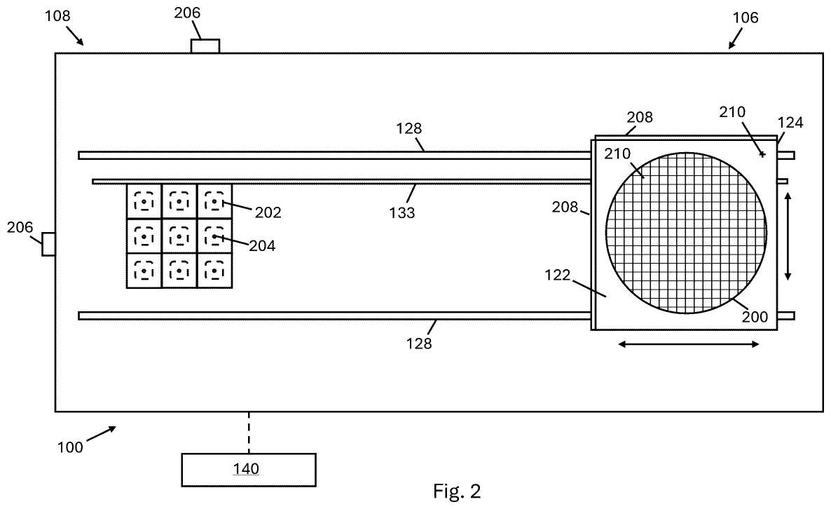

FIG. 2 is a schematic plan view of the processing tool 100. A substrate 200 is shown disposed on the support surface 122 of the stage 124. The first member 126 and second member 130 are not visible in FIG. 2. As noted above, the substrate support 120 has the ability to move the stage 122, and an object such as the substrate 200 disposed on the stage 122 in directions parallel to the first and second directions. The substrate support 120 is here movably disposed on two of the rails 128, but any number of rails 128 can be used, such as one, three, or four. In some cases, zero rails 128 can be used where, for example, the substrate support 120 moves on rollers of a suitable kind. Thus, as noted above, the substrate support 120 can move the substrate 200 between the inspection zone 106 and the processing zone 108, and for some operations of the processing tool 100, movement and positioning of the stage 124 can be controlled using the sensors 132, which are not visible in the top view of FIG. 2. A metric member 133 is shown extending in the first direction for representing position of the stage 124 along the first direction as described above.

In the arrangement of FIGS. 1 and 2, there are nine charged particle devices 150 arranged in a square array to provide the capability of processing zones of the substrate 200 independently and concurrently. Any number of charged particle devices 150 can be used. Each of the charged particle devices 150 has an exposure zone 202 that is a zone within which a surface can be illuminated using charged particles from the device 150. The exposure zone will vary linearly in areal extent with distance from the exit end of the charged particle device 150, but the exposure zones 202 depicted here are defined with reference to the support surface 122 of the substrate support 120, or with reference to the substrate 200 disposed thereon. That is, were the substrate support 120 shown here positioned to receive charged particles from the charged particle devices 150, the exposure zones 202 depicted here would represent the areas reachable by charged particles emitted from the various devices 150. Each exposure zone 202 has a central region 204 generally at or near a center of the exposure zone 202, where a maximum density of charged particles will impinge the support surface 122, or the substrate 200, when positioned to receive charged particles, at a time the controls of the charged particle devices 150 are set to neutral settings. The exact point or area of maximum density within the exposure zone, at neutral settings, depends on calibration of the charged particle device and orthogonality of the stream of charged particles emitted by the charged particle device toward the substrate support 120. It is helpful for controlling a writing process to have accurate coordinates defining where the exposure zone 202 or the central region 204 thereof, is located when the charged particle device 150 has neutral settings and given accurately known coordinates for position of the stage 124.

As mentioned above, accurate processing of substrates using charged particles is facilitated by accurate positioning of the stage 124 relative to the central regions 204 of the exposure zones 202. The processing tool 100 can have a second plurality of sensors 206 that have a second accuracy, where the sensors 132 are a first plurality of sensors that have a first accuracy, and where the second accuracy is higher than the first accuracy. Thus, the second sensors 206 can be used to position the stage 124 of the substrate support 120 with higher accuracy where such accuracy is required, for example in some charged particle processing processes. For example, where the charged particles are electron beams, the second sensors 206 can be interferometers capable of sensing position of the stage with accuracy of about 10 nm, for example 1-5 nm. Where interferometers are used as the second sensors 206, mirrors 208 can be attached to the stage 124 for use with the interferometers.

The sensors 132 and 206 can be used to determine a relationship between a position of the stage 124, for example a “home” position, and neutral positions of charged particle beams emitted by the charged particle devices 150. A known pattern 210 can be provided on the support surface 122 of the stage 124, on the substrate 200, or both, to facilitate accurate positioning of the stage 124 and determination of the relationship between position of the stage and position of the central regions 204 of the charged particle devices 150. The known pattern 210 can be used to capture digital images using the optical inspection station and the charged particle beam devices 150, and image processing software can be used to recognize the known pattern 210 and render precise measurements of the position of the known pattern using the first and second pluralities of sensors 132 and 206. Imaging the known pattern 210 using the charged particle beam devices 150 enables relating settings of the controls of the devices 150 to position of the central regions 204 measured using the sensors 206 and determined using a digital image of the known pattern 210. In one embodiment, the known pattern 210 can be a conductive recess provided in the support surface 122 of the stage 124, which can also be used for other purposes, such as calibrating control elements of one or more of the charged particle devices.

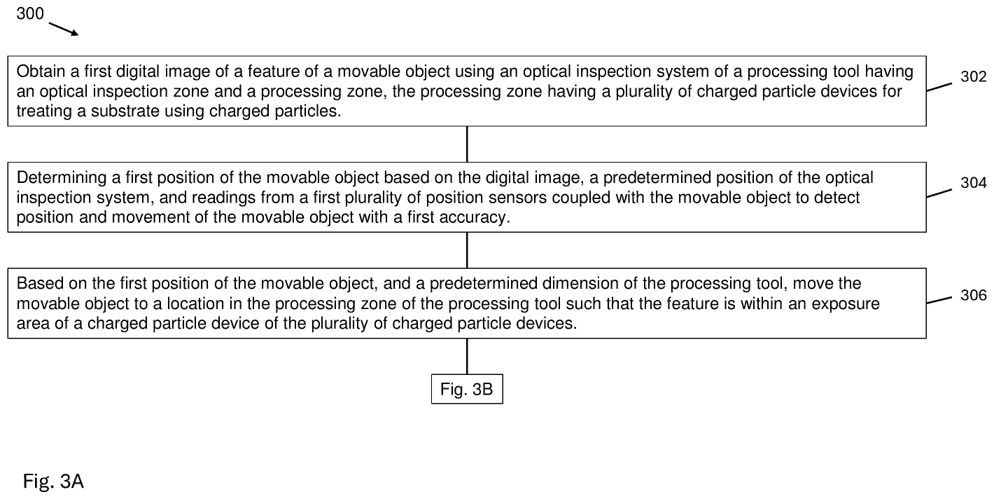

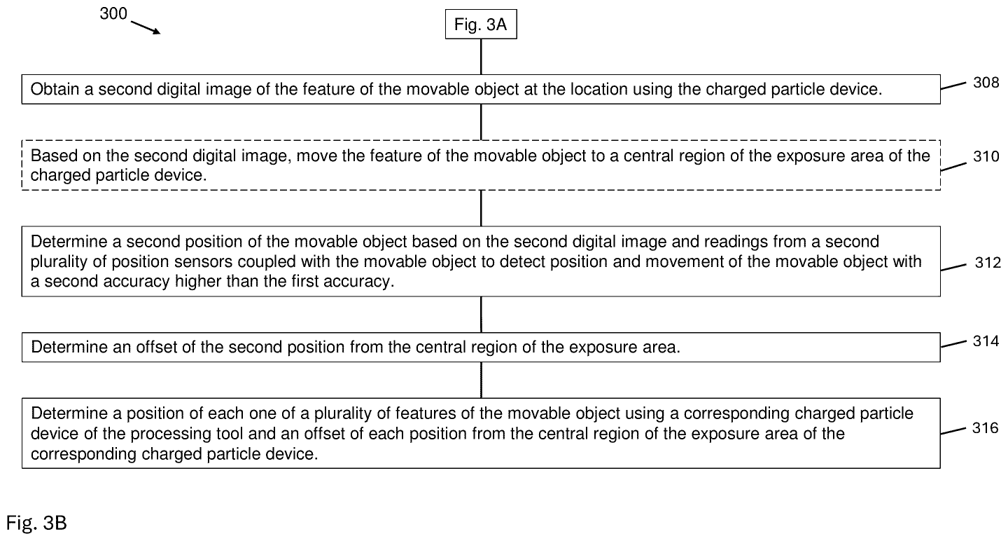

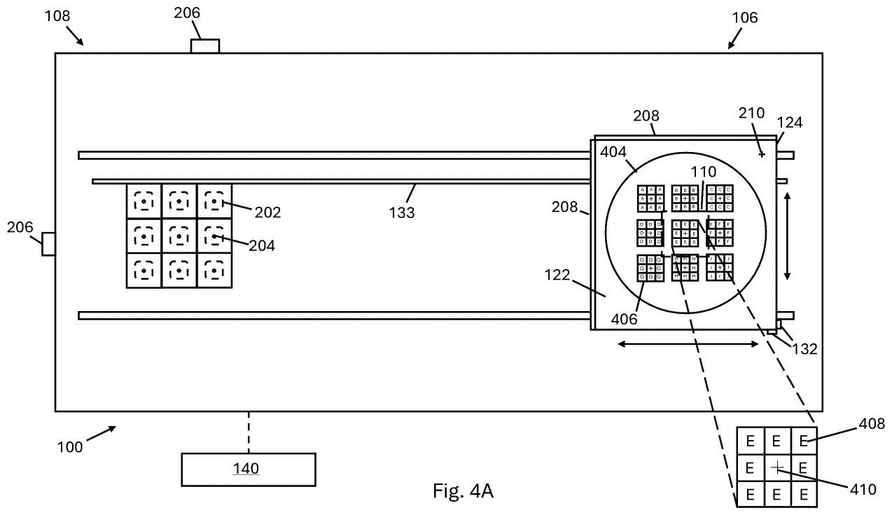

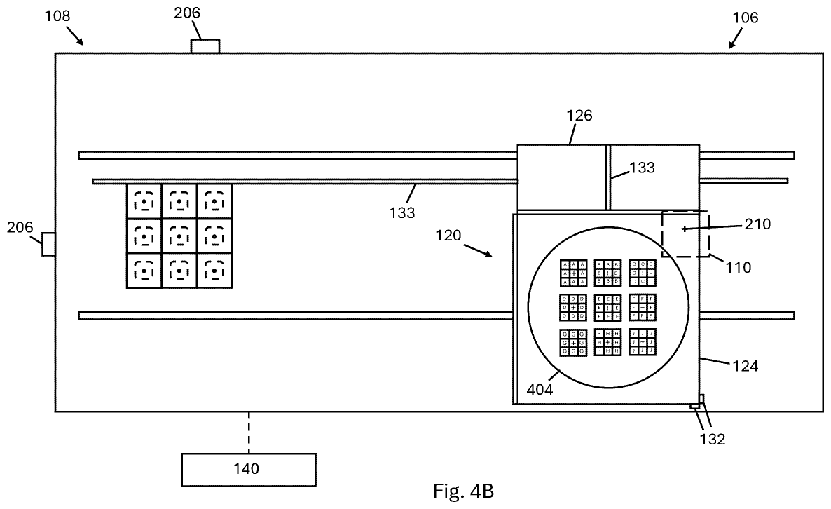

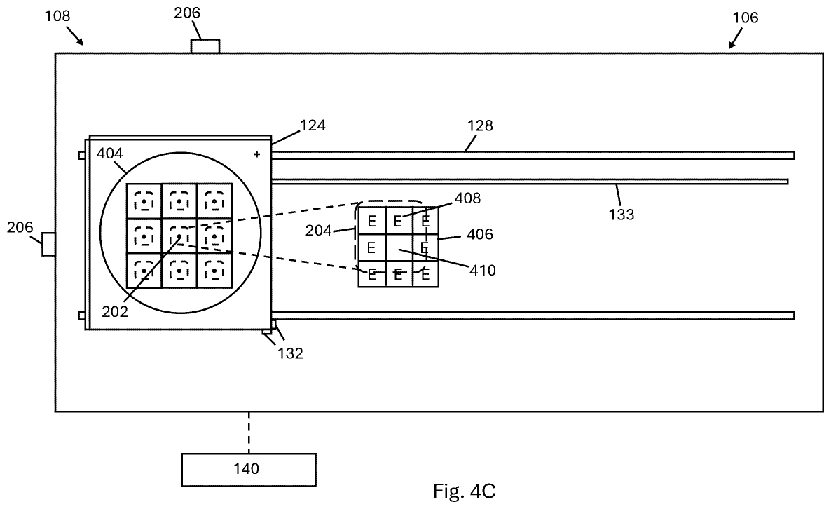

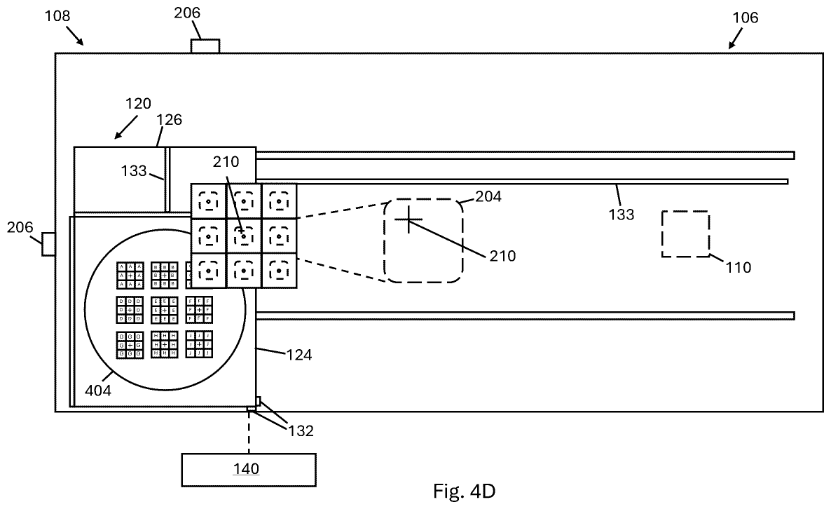

FIGS. 3A and 3B show a flow diagram summarizing a method 300 according to one embodiment. FIGS. 4A-4D are activity diagrams of the processing tool 100 at various stages of performing the method 300. The scales depicted in FIGS. 4A-4D are chosen to facilitate description of the method. Scales in real embodiments, for example the sizes of the exposure areas 202 and central regions 204, along with sizes of the features and/or patterns used for calibration, mapping, and/or relating sensor readings to real positions of tool components may be much smaller.

A digital image of a feature of a movable object is imaged at 302 using an optical inspection system of the processing tool like the processing tool 100. The optical inspection system is similar, or identical, to the optical inspection station 110, and is represented in phantom in FIG. 4A. Here, the movable object is a substrate 404, and the feature is a known pattern 406, or a portion thereof, formed on the substrate 404. The optical inspection system captures a digital image of the feature of the movable object in the optical inspection zone 106.

In this case, the known pattern 406 has content that indicates location. For example, the content of the known pattern 406 contains a grouping symbol 408 and a centering symbol 410, which can be of any suitable shape and arrangement. These symbols can be used by image processing software to determine positions within the digital image. At 304, a position of the movable object is determined based on the digital image, a predetermined position of the optical inspection system, and readings from the first plurality of position sensors 132. As shown in FIG. 4A, image processing software in common use can be used to identify the position of the movable object, in this case the substrate 404. The image processing software can recognize the centering symbol 410 of a proper feature or feature portion, for example using the grouping symbol 408. The image processing software can then determine a position of the centering symbol 410 within a coordinate system of the digital image. Using a predetermined position of the optical inspection system within the processing tool 100, the image processing software can determine a first position of the centering symbol 410, and thus of the movable object, in a coordinate system of the processing tool 100. Readings of the first plurality of sensors 132 (FIG. 1) can be related to the determined position of the movable object, as represented in this case by the centering symbol 410, and such readings can be stored for later use when bringing a substrate to the optical inspection system for inspection.

It should be noted that, in the event the centering symbol 410 is found, by the image processing software, to be displaced from a center of the field of view of the optical inspection system, as determined by the image processing software, or provided to the image processing software as a predetermined parameter, the image processing software can compute offsets in the first and second directions, and the readings of the sensors 132 can be adjusted by the amount of the offsets to represent an imaging position of the stage 124. As noted above, the imaging position determined using the image processing software can be used for positioning future substrates for optical inspection.

It should be noted that, where the movable object is a substrate such as the substrate 404, the optical inspection system can be used to image more than one feature of the movable object, and the images can be used to determine rotation of the movable object, as well as position. The optical inspection system can be used to obtain a first optical digital image of a first feature on the substrate and a second optical digital image of a second feature of the movable object. The two digital images can be used to determine a position of the movable object as well as a rotation of the movable object. For example, a first image position of the first feature within the first digital optical image can be determined using image processing, and based on the determined first image position, and on a predetermined or known position of the optical inspection system, a first global position of the first feature can be determined. Additionally, a second image position of the second feature within the second digital optical image can be determined using image processing, and based on the determined second image position, and on the predetermined or known position of the optical inspection system, a second global position of the second feature can be determined. The first and second global positions of the first and second features can be compared to predetermined or known positions of the first and second features on the substrate to compute a rotation of the substrate based on differences between the first and second global positions of the first and second features and the predetermined or known positions of the first and second features.

FIG. 4B illustrates using a feature on the support surface 122 of the stage 124 itself for optical inspection. The substrate 200 is still disposed on the stage 124 in FIG. 4B, but the substrate 404 does not need to be present for this version. Here, the stage 124, as the movable object in this case, has been positioned to place the feature 210, which is a pattern of known shape and position on the substrate support 120, within the field of view of the optical inspection station 110, shown here again in phantom to facilitate description. As the stage 124 has been moved south within the enclosure 102, the first member 126 of the substrate support 120 is visible in FIG. 4B. The optical inspection station 110 can obtain a digital image of the feature 210, and image processing software can be used to determine a position of the feature within the image. A first position of the feature 210 in the coordinate system of the processing tool 100 can be determined based readings from the first plurality of sensors 132, predetermined position of the optical inspection station 110, and on the digital image of the feature 210 taken by the optical inspection station 110. FIGS. 4A and 4B show two alternate methods of obtaining a first position, using a substrate bearing a known pattern or using a feature, as a known pattern, directly on the substrate support. For increased accuracy and precision, both methods can be used.

At 306, the first position of the movable object, and a predetermined dimension of the processing tool 100, can be used to move the movable object to a location of the processing zone such that the feature is within the exposure zone 202 of a charged particle device 150 of the processing tool 100. The charged particle device 150 to be used for this purpose can be predetermined. For example, here, the known pattern 406 formed on the substrate 404 is designed to match the layout of the charged particle devices 150 of the processing tool 100, so the predetermined dimension can be a distance from a center of the field of view of the optical inspection system to the central region 204 of the center charged particle device 150. Here, the center charged particle device 150 is used as a reference, but any charged particle device in an array of charged particle devices can be used as a reference. The predetermined dimension can have components in the first and second directions (i.e. “x” and “y” components) such that these components can be used to move the substrate support 120 such that the movable object, in this case the substrate 404, moves to a location where the feature is within the exposure area 204 of the center charged particle device 150.

FIG. 4C shows the processing tool 100 with the substrate 404, disposed on the stage 124, moved to the location to place the feature, in this case the centering symbol 410, within the exposure zone 202 of the center charged particle device 150. In the view of FIG. 4C, the known pattern 406 of the substrate 400 is obscured by the charged particle devices 150. At 308, the charged particle device, in this case the center charged particle device 150, is used to capture a second digital image of the feature of the movable object. The charged particle devices 150 can be equipped with detectors, such as back-scattered electron detectors, that enable imaging using the charged particle emitted by the devices 150. Such imaging can produce exceedingly high resolution images that can be used for high-precision measurements.

The second digital image may be captured over the entire field of view of the charged particle device or only a portion thereof. In FIG. 4C, the entire field of view of the charged particle device is depicted. Some error in positioning of the stage 124 is depicted in FIG. 4C, resulting in off-center placement of the centering symbol 410 due to imprecision in imaging using the optical inspection station 110, determining the location of the centering symbol 410 in the image, and movement of the stage to place the centering symbol 410 at the central region 204 of the center charged particle device 150. Note that movement of the stage 124 can be controlled by the controller 140 by operating the linear actuators of the substrate support 120 based on readings from the first and/or second plurality of sensors 132 and 206. As described above, the second plurality of sensors 206 has higher position measurement accuracy than the first plurality of sensors 132, so use of such sensors can reduce positioning error of the stage 124 and placement error of the feature 410, but nonetheless some imprecision may remain.

The second digital image of the field of view 204 of the center charged particle device 150 is obtained. As shown in FIG. 4C, in this case, the digital image includes a portion of the known pattern 406 formed on the substrate 404, shown here magnified and excerpted to facilitate description. Image processing software can then be used to recognize and process components of the image. For example, image processing software can recognize the centering symbol 410 within the digital image. Image processing software can also recognize a grouping symbol 408 within the image. The controller 140 can be configured to determine, using the grouping symbol 408, which portion of the known pattern 406 is captured in the image. In this case, alphanumeric symbols are used as the grouping symbols 408, and the controller 140 can be configured to determine that, based on the “E” grouping symbol obtained in the image, the portion of the known pattern 406 that has been captured in the image is the central “E” portion, and the centering symbol 410 captured in the image is the centering symbol at the center of the known pattern 406.

At 310, the stage 124 can be moved to place the feature, in this case the centering symbol 410, to the central region 202 of the charged particle device, which is the central device of the array. Image processing software can be used to determine a distance of the centering symbol 410 from the center (i.e. a central pixel) of the digital image in physical units or numbers of pixels in the first and second directions. The controller 140 can be configured to resolve, based on a predetermined image dimension, in physical units or numbers of pixels, of the field of view of the charged particle device, a distance to move the stage 124, in physical units or coordinates of the processing tool 100, to bring the feature 410 to the central region 202 of the charged particle device. For example, the controller 140 can be configured to interpolate the distance to move the stage using the image distance and the predetermined image dimension. The second plurality of sensors 206 can be used to determine when the stage has reached the central region 202. The controller 140 can be configured to receive signals from the first and/or second plurality of sensors 132 and 206 to determine when the stage 124 has reached the position bringing the feature 410 to the central region 202. When the stage 124 has reached the position, readings of the sensors 132 and 206 can be saved as representing a position of the stage 124 substantially centered at the center of the center charged particle device, in effect a “home” position of the stage 124. Thus, at 312, a second position of the movable object is determined based on the second digital image and readings from a second plurality of position sensors coupled with the movable object to detect position and movement of the movable object with a second accuracy higher than the first accuracy.

The operation 310 of moving the feature to the center of the exposure area of the charged particle device is an optional operation. At 314, the image processing software can compare the second position determined at 312 to a center coordinate of the image taken by the charged particle device to determine an offset of the feature from the central region 204 of the exposure zone 202 of the charged particle device. Assuming the entire exposure zone of the charged particle device is imaged, the image can be understood by the image processing software as a map of the exposure zone of the charged particle device. Where a portion of the exposure zone is imaged, a definition of the imaged portion can be used to map the image to the exposure zone so the offset between the feature and the central region 204 can be ascertained. Where an offset between the central region 204 and the feature is obtained, that offset can be used to control the charged particle device to point a stream of charged particles to a desired location of the substrate with high accuracy, and operation 310 may be omitted. For example, where a print plan requires processing using a charged particle device with offset determined to be O, the offset O can be added to coordinates of all write instructions for the charged particle device.

At 316 a position of each one of a plurality of features of the movable object can be determined. The features can be arranged on the movable object, for example the stage 124 or a substrate disposed on the stage 124, such that all the features of the movable object are positioned within the exposure zone of a corresponding charged particle device when the movable object is moved to place one of the features within an exposure zone of a charged particle device at 306. Each of the features is imaged using the corresponding charged particle device of the processing tool and the image processing software can be used to determine the position of each feature using the known geometry of the features on the movable object, the images of the features, and optionally known dimension and positions of the charged particle devices. For each imaged feature, the image processing software can also resolve an offset of the feature from the center of the image so that an offset can be determined for each charged particle device.

The position of the feature is determined from the image of the feature using known dimensions of the image and number of pixels between the feature and the center of the image. In one method, x and y distance from the feature to the center of the image, in image coordinates, can be determined by counting pixels in the x direction and the y direction, within the image, from the feature (an edge or center of the feature) to the center of the image. The center of the image has a known position within the image from the known dimensions of the image in physical units, pixels, or an image coordinate system. The x distance and y distance can be resolved in physical units or in the coordinate system of the processing tool 100 by comparing the x distance and the y distance to dimensions of the image and to known dimensions of the exposure zone of the charged particle device. Interpolation can be used for such computation. Alternately, the dimensions of each pixel can be used, along with the pixel count, to resolve the distances. The x distance and y distance thus resolved can be used as the offset for controlling the charged particle device during a write process, as described above. Resolving an offset for each charged particle device allows the offsets to be applied to the print plan, as described above, for each charged particle device.

FIG. 4D illustrates using the feature 210 formed directly on the stage 124 to find a “home” position of the stage 124. Based on the position of the feature 210 determined from the image obtained by the optical inspection station 110, the stage 124 has been moved to place the feature, in this case the known pattern 210 formed directly on the stage 124, within the field of view of the charged particle device, in this case the central charged particle device in order to locate a centered, or “home” position of the stage 124. Again here, the entire field of view 204 of the charged particle device is depicted as being imaged. Image processing software can be used to recognize the feature 210, having a known pattern, in the digital image obtained using the charged particle device and to determine the position of the feature 210 within the image. The controller 140 can be configured to determine, from the position of the feature 210 in the image, and from the known scale of the field of view of the charged particle device, corresponding to dimensions of the image (or portion captured in the image), and from the predetermined location of the feature 210 on the stage 124, a distance to move the stage 124 to bring the center of the stage 124 to the central region 202 of the center charged particle device.

It should be noted, in the context of the method 300 and FIGS. 4A-4D, that the movements of the stage 124 can be linear, rectilinear, curved, or along any suitable path. For example, the controller 140 can be configured to determine coordinates at which to position the stage and to operate the linear actuators of the stage together to move the stage in a single linear motion to the destination coordinates. Thus, the controller 140 can be configured to operate each linear actuator at a proportional rate such that the stage travels the requisite distance in the first direction and the second direction at the same rate and reaches the first-direction destination coordinate and the second-direction destination coordinate at the same time. Alternately, the controller 140 can be configured to operate the linear actuators to move the stage in two rectilinear motions to the destination coordinates. Thus, the controller 140 can be configured to operate one linear actuator to bring the stage to the first-direction destination coordinate and then operate the other linear actuator to bring the stage to the second-direction destination coordinate in two separate movements. Alternately, the controller 140 can be configured to plan more complex movements of the stage to bring the stage to the destination coordinates, which can include curved motions. Such movements can be performed without the use of readings from position sensors, for example by signaling the linear actuators to travel a certain distance, or readings from the position sensors can be used to determine when the stage has reached the destination coordinates. The controller 140 can be configured to receive signals from position sensors such as the first and/or second plurality of sensors 132 and 206 of the processing tool 100 to monitor position of the stage 124 as the stage is moved toward the destination coordinates and to stop movement of the stage 124 when the stage 124 reaches the destination coordinates.

As noted above, the method 300 can be used to position the stage 124 of the processing tool 100 at a center of a chosen charged particle device among an array of charged particle devices in the processing tool 100, which can be any of the charged particle devices in the array. It can also be useful, in controlling a process performed using the charged particle devices 150, to ascertain a coordinate location of a neutral position of the stream of charged particles emitted by each charged particle device. Using such information, settings of the controls of each charged particle device can be mapped to a position of the emission field of the charged particles at the support surface 122 of the stage 124. A substrate, such as the substrate 404, having the known pattern 406, can be used to ascertain such positions. Where the substrate support of the processing tool has sufficient movement scope, the feature 210 formed on the substrate support can also be used to ascertain such positions. It should be additionally noted here that, where a substrate is used to ascertain the positions, one or more of the charged particle devices can be used to image two or more features on the substrate to determine a rotation of the substrate using charged particle images according to a procedure similar to that described above in reference to the optical inspection system. First and second charged particle images of a first and second feature of the substrate can be obtained and, using image processing, readings of the second sensors, and a procedure similar to that described above in reference to the optical inspection system, the first and second charged particle images can be used to determine the rotational offset of the substrate.

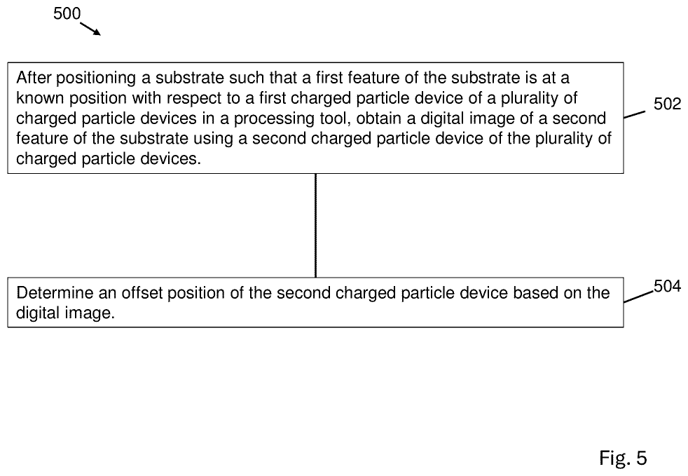

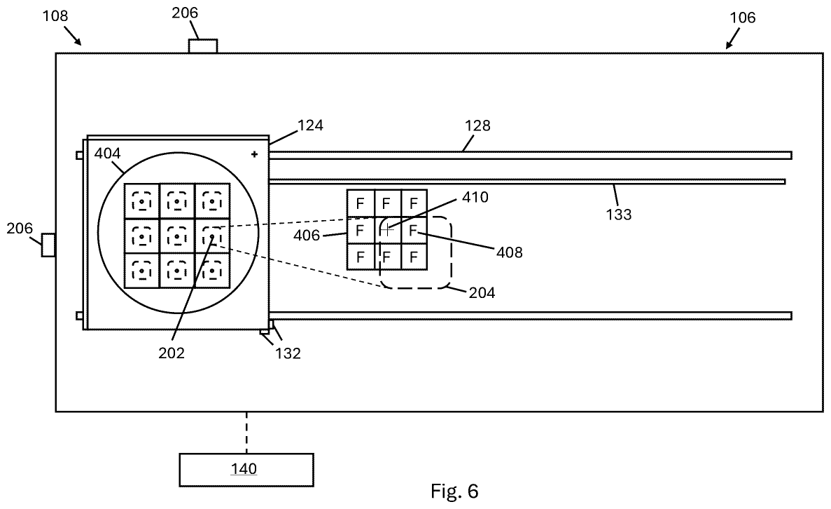

FIG. 5 is a flow diagram summarizing a method 500 according to another embodiment. The method of FIG. 5 uses a substrate having a known pattern to ascertain the neutral positions of a stream of charged particles produced by an array of modular miniature charged particle devices in a processing tool. With the substrate having the known pattern positioned at a location such that a first feature of the known pattern is at a known position with respect to a first charged particle device, at 502 a digital image is obtained of a portion of the known pattern of the substrate using a second charged particle device. The known pattern may contain a second feature that is captured in the digital image. FIG. 6 depicts the captured image. As before, there may be some error or displacement in position of the known pattern with respect to the second charged particle device. For example, the dimensions of the known pattern might not exactly match the dimensions of the processing tool (i.e. spacing of the charged particle devices) or the neutral position of the stream of charged particles might be different from the expected neutral position.

At 504, an offset position of the second charged particle device is determined based on the digital image. As before, image processing software can recognize and locate the centering symbol 410 captured in the image and can recognize the grouping symbol 408 capture in the image. The image processing software can determine a location of the centering symbol 410 within the image and a distance from the centering symbol 410 to a center of the image in physical units or pixels. The controller 140, or the image processing software (or both if the controller 140 is running the image processing software), can be configured to use the predetermined dimension of the field of view of the charged particle device, as above, to ascertain the distance from the centering symbol 410 to the center of the image in physical units or in coordinates of the processing tool. The controller 140 can be configured to determine, using the grouping symbol 408 captured in the image, which charged particle device captured the image, and can relate the offset distance determined from the image with the charged particle device. The controller 140 can also be configured to determine a neutral position of the stream of charged particles emitted by the charged particle device in coordinates of the processing tool 100.

This process can be repeated for each charged particle device of the array to determine offsets for each device, and optionally to determine coordinates of the neutral position of each charged particle device. Use of the methods 300 and 500 together yield an accurate calibration of the processing tool 100 relating the position of the emission fields of the charged particle devices to coordinates of the processing tool 100 and to readings of the sensors 132 and/or 206. The method 500 relies on using a substrate having a known pattern with a plurality of features for positioning the stage and ascertaining the offsets. It should also be noted here that, instead of using one charged particle device (or more than one) to image two or more features on a substrate to determine rotational offset of the substrate, multiple images of one feature using multiple charged particle devices can be used to determine a rotational offset of a substrate. For example, where offsets for an array of charged particle devices are obtained using procedures described herein, position offsets can be obtained using a feature of a subsequent substrate, and those position offsets can be compared, canceling the known position offsets of the charged particle devices, to determine a rotational offset of the substrate.

The substrate 404 described above uses features formed thereon to expedite the process of identifying offsets for each charged particle device. In an alternate method, a substrate having only a centering symbol, with no grouping symbols, can be used to identify the offset for each device by moving the stage to place the centering symbol at the expected location of the field of view of each charged particle device. Where the field of view of the devices is very small, such as for example 30 μm or less, it can be difficult to reliably place the centering symbol into the field of view of each device, so some searching can be needed to locate the centering symbol in the field of view. Using more detailed known patterns, such as on the substrate 404, can reduce the time needed to ascertain the offsets.

Precision can be improved by using only a single feature for positioning the stage and ascertaining the offsets. Once the centered position of the substrate support, placing the center of the stage at the central region of the field of view (which is substantially the same as the emission field) of the chosen (i.e. center) charged particle device, has been found, the single feature used to position the substrate support can be used to determine offsets for all the charged particle devices. Based on predetermined positions of the emission fields of the charged particle devices of the tool, the stage of the substrate support can be moved to place the single feature at the expected location of the central region of each charged particle device in turn. At each location, the single feature can be imaged using the charged particles of the charged particle device, imaging software can be used to find the feature and determine its distance from the center of the image, and the controller can render the distance as an offset in physical units or coordinates of the processing tool using the procedures defined above. Using a single feature to obtain offsets for all the charged particle streams at neutral settings can reduce error by reducing any error contribution from imprecision in positioning (or other parameters such as scale and distortion) of features on the substrate.

When a processing tool such as the processing tool 100 has been analyzed to determine positional and operating relationships of its components, as described above, the information obtained can be used to process substrates expeditiously. Processing tools like the processing tool 100 are used to process substrates using multiple miniature modular charged particle devices to process portions of the substrate concurrently, in order to reduce the time required for completing a treatment plan of the entire substrate. The treatment plan is divided among the charged particle devices, and multiple portions of the substrate are treated concurrently to reduce processing time.

In one method, the treatment plan is reduced to a series of writing instructions for each charged particle device and movement instructions for the substrate support. In most cases, the substrate is processed in scan paths where the charged particle devices write in stripes across the substrate. The substrate is typically moved at a constant velocity in a scan direction while streams of charged particles are emitted from the charged particle devices to write patterns at different locations in the stripes. When processing of a set of stripes is complete, if the entire substrate has not been processed and more of the treatment plan needs to be performed, a second scan is performed using a second scan path different from the first scan path so that different stripes are written in the second scan. The second scan path may be implemented by scanning in the same direction as the first scan path, or in an opposite direction. Thus, the substrate can be processed using a boustrophedonic movement pattern along with a treatment plan designed to write desired patterns on the substrate surface according to such a movement plan.

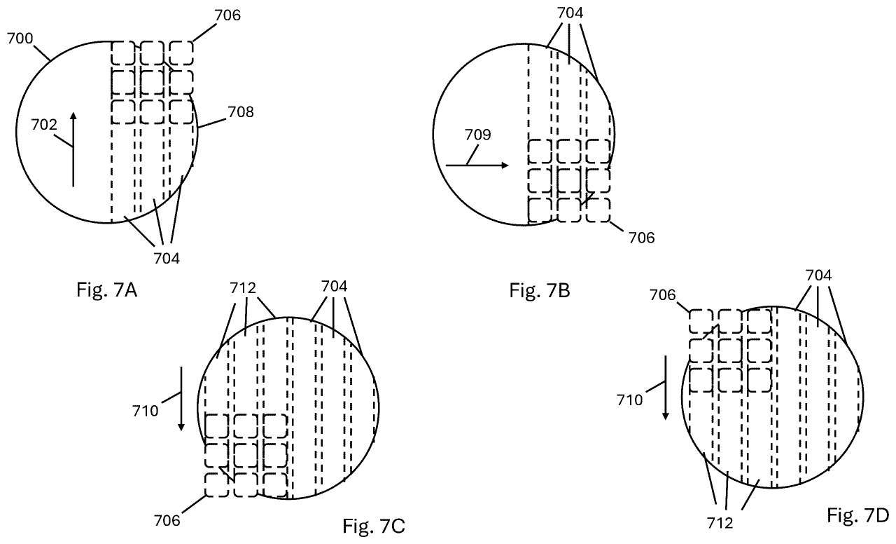

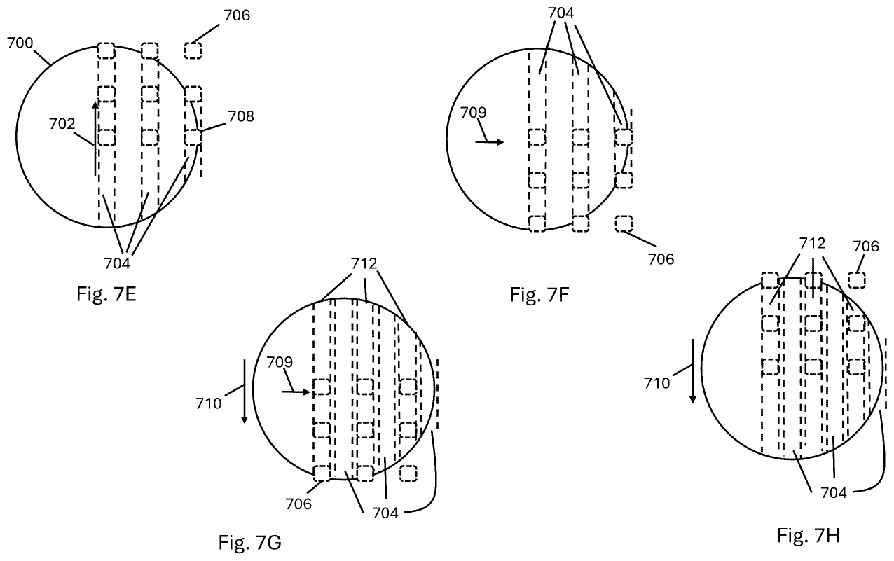

FIGS. 7A-7D are activity diagrams illustrating processing of a substrate using a processing tool that has multiple miniature modular charge particle devices. The substrate 700 is moved along a first scan path 702 in FIG. 7A to process a first plurality of stripes 704 on the substrate 700. In this example, there are nine charged particle devices, which can be the charged particle devices 150 of the processing tool 100. The charged particle devices here have emission fields 706 shown using dashed lines. The first scan path 702 locates the first plurality of stripes 704 to include exposing near an edge 708 of the substrate 700. As the substrate 700 is moved at a constant velocity along the scan path 702, the charged particle devices are controlled to execute a portion of a treatment plan for the substrate 700. The streams of charged particles emitted by the charged particle devices to the emission fields 706 are manipulated to write patterns on the substrate 700 in the stripes 704 until the first scan path 702 is complete.

FIG. 7B shows the substrate 700 positioned at the completion of the first scan path 702. Following completion of the first scan path 702, the substrate 700 is moved to position untreated portions of the substrate 700 for exposure in the emission fields 706 of the charged particle devices in order to complete the treatment plan for the substrate 700. A transfer movement 709 is shown in FIG. 7B to move the substrate 700 in a direction transverse to the direction of the first scan path 702 so that the rest of the treatment plan can be completed.

FIG. 7C shows the substrate 700 positioned following the transfer movement 709. The substrate 700 is then moved along a second scan path 710, which in this case is in an opposite scan direction from the first scan path 702. As the substrate 700 is moved along the second scan path, the charged particle devices are controlled to write patterns, according to the treatment plan, in a plurality of second stripes 712, as the substrate scans at a constant velocity along the second scan path 710. FIG. 7D shows the substrate 700 at the completion of the second scan path 710. It should be noted that the scan paths and stripes depicted in FIGS. 7A-7D do not treat the entire surface of the substrate 700. The treatment plan can thus include treatment in overlapping stripes to treat the entire surface of the substrate 700. Such treatment is not illustrated here to simplify the drawings.

Where the positional relationships of the components are known prior to starting a treatment of a substrate, any situations that arise with the components of the tool can be compensated by changes to the treatment plan. Offsets computed above based on imaging features of a movable object using the charged particle devices can be reflected in adjustments to the treatment plan. For example, coordinates for writing on the substrate using streams of charged particles can be adjusted by the amount of the positional offset of the relevant stream. During execution of a treatment plan such as shown in FIGS. 7A-7D, compensation can be made for such offsets, and for other issues including charged particle devices that cannot be operated for at least some portion of the treatment plan.

FIGS. 7E-7H are activity diagrams illustrating processing of a substrate in a manner similar to that shown in FIGS. 7A-7D, but with one difference. In FIGS. 7A-7D the scan paths are close together, so that adjacent stripes of the substrate being processed are processing using electrons beams that are very close together. In the process illustrated in FIGS. 7E-7H, the electrons beams are spaced apart to reduce any potential interference of the beams, and processing of stripes is interleaved. Thus, in FIG. 7E, three stripes 704, spaced apart by a distance larger than a dimension of any of the electron beams, are processed using the first scan path 702. Note that, in this case, one of the stripes 704 encompasses the edge 708 of the substrate 700. In FIG. 7F, as in FIG. 7B, the substrate is moved to position untreated portions of the substrate 700. In this case, untreated portions of the substrate 700 are between treated stripes 704. In FIG. 7G, then, the substrate 700 is moved along the second scan path 710 to treat a plurality of second stripes 712 that are interleaved with the first stripes 704, and in 7H, the first plurality of stripes 704 and the second plurality of stripes 712 of processed areas of the substrate are achieved with similar close spacing as shown in FIG. 7D, but with electrons beams having larger spacing. As shown here, the electron beams may be spaced at a two-stripe pitch to allow processing of stripes at a desired spacing but interleaved to minimize any interference of adjacent beams or processing.

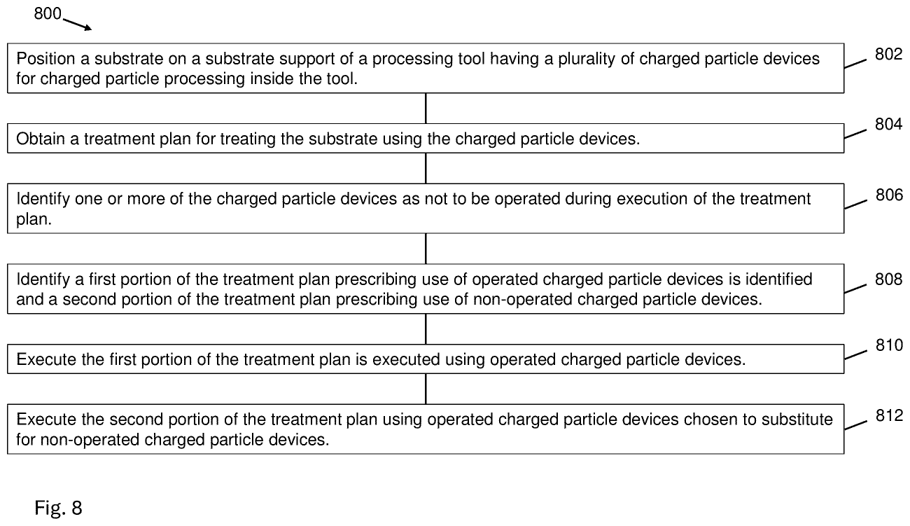

FIG. 8 is a flow diagram summarizing a method 800 according to another embodiment. The method 800 benefits from prior determination of positional relationships of components of a charged particle device processing tool having a plurality of charged particle devices. The method 800 is a method of processing a substrate using such a tool where one or more of the charged particle devices is not operated for some reason. The device might be inoperative, or the device might have specifications or tolerances insufficient to perform certain processing. In any event, a treatment plan for a substrate requires one or more charged particle devices of the array be idled for one or more durations or scan distances.

At 802, a substrate is positioned on a substrate support of a processing tool having a plurality of charged particle devices for charged particle processing inside the tool. At 804, a treatment plan for treating the substrate using the charged particle devices is obtained. At 806, one or more of the charged particle devices are identified as not to be operated during execution of the treatment plan. The non-operated charged particle devices may be inoperative, out of spec, or incapable of performing the treatment plan for a variety of possible reasons. In any event, some compensation must be made because the treatment plan prescribes use of the non-operated charged particle devices.

At 808, a first portion of the treatment plan prescribing use of operated charged particle devices is identified and a second portion of the treatment plan prescribing use of non-operated charged particle devices is identified. This method uses operated charged particle devices to treat portions of the substrate designated for treatment, in the treatment plan, using non-operated charged particle devices.

At 810, the first portion of the treatment plan is executed, in which the substrate is treated using operated charged particle devices. Portions of the substrate are treated using operated charged particle devices according to the original prescription of the treatment plan. This treatment can be performed during a first scan of the substrate.

At 812, the second portion of the treatment plan is executed, in which the substrate is treated using operated charged particle devices chosen to substitute for non-operated charged particle devices. This treatment can be performed during a second scan of the substrate. The first scan and the second scan can have identical scan paths or different scan paths. In any event, the operated charged particle device chosen to treat portions of the substrate designated for treatment, in the treatment plan, using a non-operated charged particle device is usually adjacent to the non-operated charged particle device, either in the direction of the second scan or in a direction transverse to the direction of the second scan.

The second scan, using operated charged particle devices in place of non-operated charged particle devices can be controlled using a controller configured to modify execution of the treatment plan to avoid using non-operated device and to use operated devices instead, or the treatment plan can be adjusted, prior to execution, to replace designation of non-operated devices in the treatment plan with designations of operated devices selected to be adjacent to the replaced non-operated device. Where substitution of an operated device for a non-operated device requires a change in movement of the substrate to bring a portion of the substrate into the emission field of the substitute device, movement of the substrate can be changed to accommodate the different scan path required to expose the substrate. For example, the scan stroke can be extended in multiples of one pitch of the charged particle devices, either in the direction of the scan paths or in a direction transverse to the scan paths. Additionally, where suitable and convenient, two or more operated charged particle devices can be used to process a portion of a substrate prescribed in a treatment plan for processing by a non-operated charged particle device.

While the foregoing is directed to embodiments of the present invention, other and further embodiments of the present disclosure may be devised without departing from the basic scope thereof, and the scope thereof is determined by the claims that follow.

We claim:

1. A method, comprising:
obtaining a first digital image of a feature of a movable object using an optical inspection system of a processing tool having an optical inspection zone and a processing zone, the processing zone having a plurality of charged particle devices for treating a substrate using charged particles;
determining a first position of the movable object based on the digital image, a predetermined position of the optical inspection system, and readings from a first plurality of position sensors coupled with the movable object to detect position and movement of the movable object with a first accuracy;
based on the first position of the movable object, and a predetermined dimension of the processing tool, moving the movable object to a location in the processing zone of the processing tool such that the feature is within an exposure area of a charged particle device of the plurality of charged particle devices;
obtaining a second digital image of the feature of the movable object at the location using the charged particle device; and
determining a second position of the movable object based on the second digital image and readings from a second plurality of position sensors coupled with the movable object to detect position and movement of the movable object with a second accuracy higher than the first accuracy.

2. The method of claim 1, wherein the first accuracy is within 10 micrometers and the second accuracy is within 100 nanometers.

3. The method of claim 1, wherein each of the position sensors of the second plurality of position sensors is an interferometer.

4. The method of claim 3, wherein each of the position sensors of the first plurality of position sensors is an encoder.

5. The method of claim 1, wherein the movable object is a substrate stage.

6. The method of claim 1, wherein the movable object is a substrate disposed on a movable substrate stage.

7. The method of claim 1, wherein the feature of the movable object is a first feature, the first digital image is a first optical digital image, and further comprising;
obtaining a second optical digital image of a second feature of the movable object using the optical inspection system;
determining a third position of the movable object based on the second optical digital image, a predetermined position of the optical inspection system, and readings from the first plurality of position sensors; and
based on the first position and the third position of the movable object, determining a rotational offset of the movable object.

8. The method of claim 1, further comprising obtaining a digital image of each feature of a plurality of features of the substrate, each feature corresponding to one charged particle device of the plurality of charged particle devices, using the corresponding charged particle device; and
based on each digital image, determining an offset position of the corresponding charged particle device.

9. A method, comprising:
obtaining a first digital image of a feature of a movable object using an optical inspection system of a processing tool having an optical inspection zone and a processing zone, the processing zone having a plurality of charged particle devices;
determining a first position of the movable object based on the digital image, a predetermined position of the optical inspection system, and readings from a first plurality of position sensors coupled with the movable object to detect position and movement of the movable object with a first accuracy;
based on the first position of the movable object, and a predetermined dimension of the processing tool, determining a second position within an exposure area of a charged particle device of the plurality of charged particle devices;
moving the movable object to position the feature at the second position by moving the movable object in a linear direction until readings from the first plurality of position sensors indicate that the feature is located at the second position;
obtaining a second digital image of the feature of the movable object at the second position using the charged particle device; and
based on the second digital image, and on readings from a second plurality of position sensors coupled with the movable object to detect position and movement of the movable body with a second accuracy higher than the first accuracy, determining an offset of the charged particle device.

10. The method of claim 9, further comprising:
moving the movable object such that a single feature of the movable object is sequentially located within the exposure area of each charged particle device of the plurality of charged particle devices;
obtaining a digital image of the single feature using each charged particle device of the plurality of charged particle devices; and
for each charged particle device,
based on the digital image of the single feature, and on readings obtained using the second plurality of position sensors, identifying an offset between a position of the single feature in the digital image and a central location of the exposure area of the charged particle device.

11. The method of claim 10, further comprising defining coordinates of the central location of each charged particle device based on the digital images of the single feature and on the readings obtained using the second plurality of position sensors.

12. The method of claim 11, wherein identifying an offset between the position of the single feature in the digital image and the central location of the exposure area comprises using an interpolation process to calculate the offset.

13. The method of claim 9, wherein the digital image of the single feature is a first charged particle image and the offset is a position offset, and further comprising:
obtaining a second charged particle image of a second feature of the movable object using one or more of the charged particle devices; and
based on the first and second charged particle images, identifying a rotation offset of the movable object.

14. The method of claim 9, wherein each of the position sensors of the first plurality is an encoder, each of the position sensors of the second plurality is an interferometer, and the movable object is a substrate disposed on a movable stage.

15. The method of claim 9, further comprising obtaining a digital image of each feature of a plurality of features of the substrate, each feature corresponding to one charged particle device of the plurality of charged particle devices, using the corresponding charged particle device; and
based on each digital image, determining an offset position of the corresponding charged particle device.

16. A method, comprising:
obtaining a first digital image of a first feature of a movable object using an optical inspection system of a processing tool having an optical inspection zone and a processing zone, the processing zone having a plurality of charged particle devices;
determining a first position of the movable object based on the first digital image, a predetermined position of the optical inspection system, and readings from a first plurality of position sensors coupled with the movable object to detect position and movement of the movable object with a first accuracy;
based on the first position of the movable object, and a predetermined dimension of the processing tool, determining a second position within an exposure area of a first charged particle device of the plurality of charged particle devices;
moving the movable object to position the first feature at the second position by moving the movable object in a linear direction until readings from the first plurality of position sensors indicate that the first feature is at the second position;
obtaining a second digital image of the first feature of the movable object at the second position using the first charged particle device;
based on the second digital image, and on readings from a second plurality of position sensors coupled with the movable object to detect position and movement of the movable body with a second accuracy higher than the first accuracy, determining an offset of the first charged particle device;
while the first feature is at the second position, obtaining a third digital image of a second feature of the movable object using a second charged particle device of the plurality of charged particle devices; and
based on the third digital image, and on readings from the second plurality of position sensors, determining an offset of the second charged particle device.

17. The method of claim 16, further comprising obtaining a digital image of each feature of a plurality of features of the substrate, each feature corresponding to one charged particle device of the plurality of charged particle devices, using the corresponding charged particle device; and
based on each digital image, determining an offset position of the corresponding charged particle device.

18. A method, comprising:
positioning a substrate on a movable substrate support to receive charged particles from a plurality of charged particle devices to the substrate;
obtaining a treatment plan defining treatment of portions of the substrate using the plurality of charged particle devices;
identifying one or more non-operated charged particle devices of the plurality of charged particle devices that are not to be operated during execution of the treatment plan;
identifying a first portion of the treatment plan prescribing use of operated charged particle devices to be operated during execution of the treatment plan and a second portion of the treatment plan prescribing use of non-operated charged particle devices that are not to be operated during execution of the treatment plan;
treating the substrate according to the first portion of the treatment plan using the operated charged particle devices; and
treating the substrate according to the second portion of the treatment plan using one or more of the operated charged particle devices.

19. The method of claim 18, further comprising adjusting the treatment plan to replace designations, in the treatment plan, of one or more non-operated charged particle devices with designation of an adjacent operated charged particle device.

20. The method of claim 18, wherein treating the substrate according to the first portion of the treatment plan comprises scanning the substrate in a first scan, and treating the substrate according to the second portion of the treatment plan comprises scanning the substrate in a second scan.
